(19) United States
(12) Patent Application Publication
(10) Pub. No.: US 2009/0243121 A1
(43) Pub. Date: Oct. 1, 2009

(54) SEMICONDUCTOR INTEGRATED CIRCUIT AND LAYOUT METHOD FOR THE SAME

(75) Inventor: Tomokazu ITO, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/416,492

(22) Filed: Apr. 1, 2009

(30) Foreign Application Priority Data
Apr. 1, 2008 (JP) 2008-095517

(51) Int. Cl. H01L 23/48; G06F 17/50

(52) U.S. Cl. 257/774; 716/5; 716/12; 257/E23.011

(57) ABSTRACT

A semi conductor integrated circuit includes a first via-contact configured to connect a first interconnection pattern provided for a first interconnection layer and a second interconnection pattern provided for a second interconnection layer, and a second via-contact configured to connect a third interconnection pattern provided for the first interconnection layer and the second interconnection pattern. A redundant interconnection pattern is formed in the first interconnection layer and configured to connect the first interconnection pattern and the third interconnection pattern to overlap above the second interconnection pattern.

### INCORPORATION BY REFERENCE

This patent application claims priority on convention based on Japanese Patent Application No. 2008-095517. The disclosure thereof is incorporated here in by reference.

### BACKGROUND OF THE INVENTION

1. Field of the Invention

The present invention relates to a semiconductor integrated circuit and a layout method for the semiconductor integrated circuit.

2. Description of Related Art

With size reduction and high integration in a semiconductor integrated circuit, the number of via-contacts has increased arid quality of the via-contacts has affected quality of the semiconductor integrated circuit. To improve manufacturing quality of the semiconductor integrated circuit and prevent a defect, the semiconductor integrated circuit having a redundant via-contact has employed as described in Japanese Patent Application Publication (JP-P2007-115959A).

In Japanese Patent Application Publication (JP-P2007-115959A) is described a redundant via-contact structure having a small occupied area. The via-contact structure has a first and second via-contact lands, and a plurality of via-holes formed in an insulating layer between first and second inter-connection layers. Also, the via-contact structure has a via-contact forming area formed in the first interconnection layer and including the plurality of via-holes. The via-contact forming area extends in a main interconnection direction of the first interconnection layer while not extending in a second main interconnection direction of the second interconnection layer The second via-contact land has an area formed on the second interconnection layer, extended in the second main interconnection direction, but not extended a first main interconnection direction.

In a related art, a sufficient area is ensured around an existing via-contact, and then a new via-contact and a new interconnection corresponding to the existing via-contact are formed. If an area for arranging the new via-contact cannot be ensured, the new via-contact cannot be arranged.

### SUMMARY

In an aspect of the present invention, a semiconductor integrated circuit includes: a first via-contact configured to connect a first interconnection pattern provided for a first interconnection layer and a second interconnection pattern provided for a second interconnection layer; a second via-contact configured to connect a third interconnection pattern provided for the first interconnection layer and the second interconnection pattern; a redundant interconnection pattern formed in the first interconnection layer and configured to connect the first interconnection pattern and the third interconnection pattern to overlap above the second interconnection pattern.

In another aspect of the present invention, a layout method of a semiconductor integrated circuit, is achieved: by determining an interconnection layout of a semiconductor integrated circuit based on a netlist, a cell library and a connection rule; by specifying a first interconnection layer, a second interconnection layer, a first via-contact and a second via-contact, wherein an interlayer insulating film is provided between the first interconnection layer and the second interconnection layer, and the first and second via-contacts are formed in the interlayer insulating film, and applied with a same voltage; by checking whether or not a line between the first and second via-contacts extends along one of an X-axis and a Y-axis; by checking a first interconnection pattern in the first interconnection layer of whether or not the first interconnection pattern is provided to connect the first and second via-contacts at their first ends, when the line extends along one of the X-axis and the Y-axis; by checking whether or not the first interconnection pattern is a linear pattern; by providing a redundant interconnection pattern to connect the first and second via-contacts at their second ends opposite to the first ends, when the first interconnection pattern is a linear pattern; and by performing a design rule check on an interconnection layout with the redundant interconnection pattern added.

According to the present invention, a redundant via-contact can be formed without depending presence or absence of an area for arranging a new via-contact.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a plan view showing a configuration of a semiconductor integrated circuit according to a first embodiment of the present invention;

FIGS. 2A and 2B are plan views showing the configuration of the semiconductor integrated circuit in the first embodiment for each interconnection layer;

FIG. 3 is a sectional view showing a configuration of the semiconductor integrated circuit in the first embodiment;

FIG. 4 is a perspective view showing a configuration of the semiconductor integrated circuit in the first embodiment;

FIG. 5 is a perspective view showing a configuration of the semiconductor integrated circuit without a redundant interconnection;

FIG. 6 is a block diagram showing a configuration of a semiconductor design supporting apparatus of the present invention;

FIG. 7 is a flow chart showing an operation of the semiconductor design supporting apparatus in the first embodiment;

FIG. 8 is a plan view showing a configuration of the semiconductor integrated circuit according to a second embodiment of the present invention;

FIGS. 9A and 9B are plan views showing a configuration of the semiconductor integrated circuit in the second embodiment for each interconnection layer;

FIG. 10 is a perspective view showing a configuration of the semiconductor integrated circuit in the second embodiment; and

FIG. 11 is a flow chart showing an operation of the semiconductor design supporting apparatus in the second embodiment.

### DESCRIPTION OF THE PREFERRED EMBODIMENTS

Hereinafter, a semiconductor integrated circuit of the present invention will be described in detail with reference to the attached drawings.

### First Embodiment

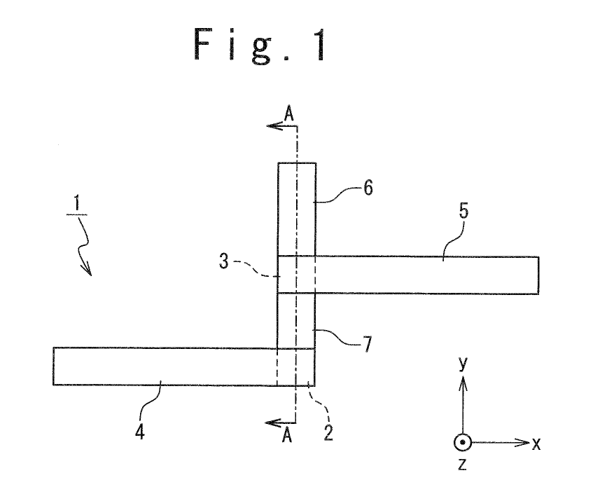

FIG. 1 is a plan view showing a configuration of a semiconductor integrated circuit 1 according to a first embodiment of the present invention. Referring to FIG. 1, the semiconductor integrated circuit 1 includes a first via-contact 2, a second via-contact 3, a first upper layer interconnection 4, a second upper layer interconnection 5, a lower layer interconnection 6 and a redundant interconnection 7. The first via-contact 2 and the second via-contact 3 are formed in an interlayer insulating film (not shown). The first upper layer interconnection 4 and the second upper layer interconnection 5 are formed in an upper layer on the interlayer insulating film. The lower layer interconnection 6 is formed in a lower layer under the interlayer insulating film. The redundant interconnection 7 connects the first via-contact 2 to the second via-contact 3 in the upper layer on the interlayer insulating film.

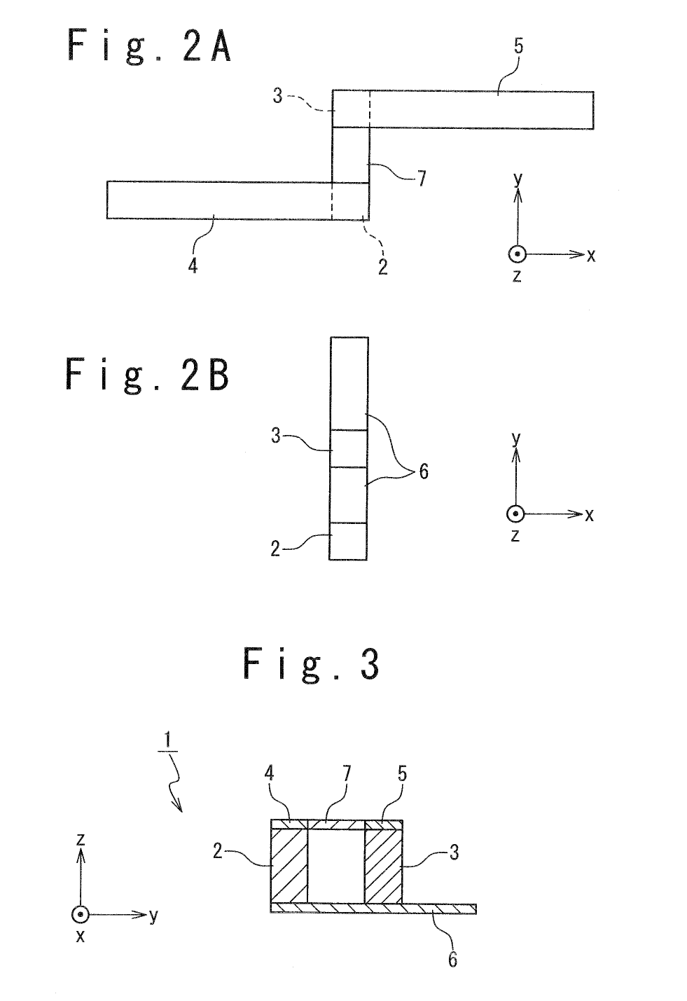

FIGS. 2A and 2B are plan views showing each interconnection layer in the semiconductor integrated circuit 1 in the first embodiment. FIG. 2A shows an upper layer interconnection portion formed on the interlayer insulating film having the first via-contact 2 or the second via-contact 3. FIG. 2B shows a lower layer interconnection portion formed under the interlayer insulating film. As shown in FIG. 2A, the semiconductor integrated circuit 1 has the redundant interconnection 7 connecting the first via-contact 2 to the second via-contact 3 in the upper layer interconnection portion on the interlayer insulating film. As shown in FIG. 2B, in a lower layer interconnection portion under the interlayer insulating film, the first via-contact 2 is connected to the second via-contact 3 by the lower layer interconnection 6.

FIG. 3 is a sectional view showing a configuration of the semiconductor integrated circuit 1 in the first embodiment. As shown in FIG. 3, the first upper layer interconnection 4 in the upper layer interconnection portion is in contact with an upper end of the first via-contact 2. A lower end of the first via-contact 2 is in contact with the lower layer interconnection 6. The second upper layer interconnection 5 in the upper layer interconnection portion is in contact with an upper end of the second via-contact 3. A lower end of the second via-contact 3 is in contact with the lower layer interconnection 6. Here, in the present embodiment, the redundant interconnection 7 and the first upper layer interconnection 4 or the second upper layer interconnection 5 are formed in the same interconnection layer, to connect the first upper layer interconnection 4 to the second upper layer interconnection 5.

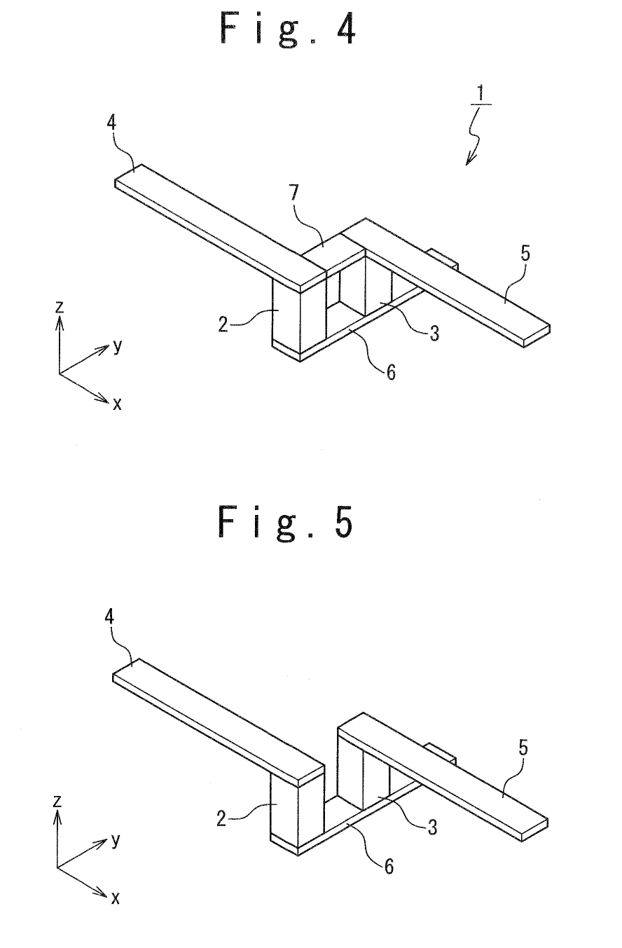

FIG. 4 is a perspective view showing a configuration of the semiconductor integrated circuit 1 in the first embodiment. As shown in FIG. 4, the first via-contact 2 is connected to the second via-contact 3 by the lower layer interconnection 6 in the lower layer portion and by the redundant interconnection 7 in the upper layer portion. Thus, the first via-contact 2 and the second via-contact 3 act as redundant via-contacts to each other. Since the first via-contact 2 and the second via-contact 3 are the redundant via-contacts, improvement in reliability of the semiconductor integrated circuit 1 and improvement in yield can be achieved.

### COMPARATIVE EXAMPLE

A comparison example will be described below to facilitate understanding of the present invention. FIG. 5 is a perspective view showing a configuration of the semiconductor integrated circuit 1 without the redundant interconnection 7 in the comparison example. As shown in FIG. 5, in the semiconductor integrated circuit 1 in the comparison example the first upper layer interconnection 4 is connected to the lower layer interconnection 6 by only the first via-contact 2 and the second upper layer interconnection 5 is connected to the lower layer interconnection 6 by only the second via-contact 3. If the first via-contact 2 is not suitably formed, connection between the first upper layer interconnection 4 and the lower layer interconnection 6 is broken in the semiconductor integrated circuit 1 in the comparison example. Similarly, if the second via-contact 3 is not suitably formed, connection between the second upper layer interconnection 5 and the lower layer interconnection 6 is broken.

In the semiconductor integrated circuit 1 in the present embodiment, if one of the first via-contact 2 and the second via-contact 3 is not suitably formed, the other acts as the redundant via-contact. For this reason, even if the first via-contact 2 is not suitably formed, the first upper layer interconnection 4 is suitably connected to the lower layer interconnection 6 by the second via-contact 3.

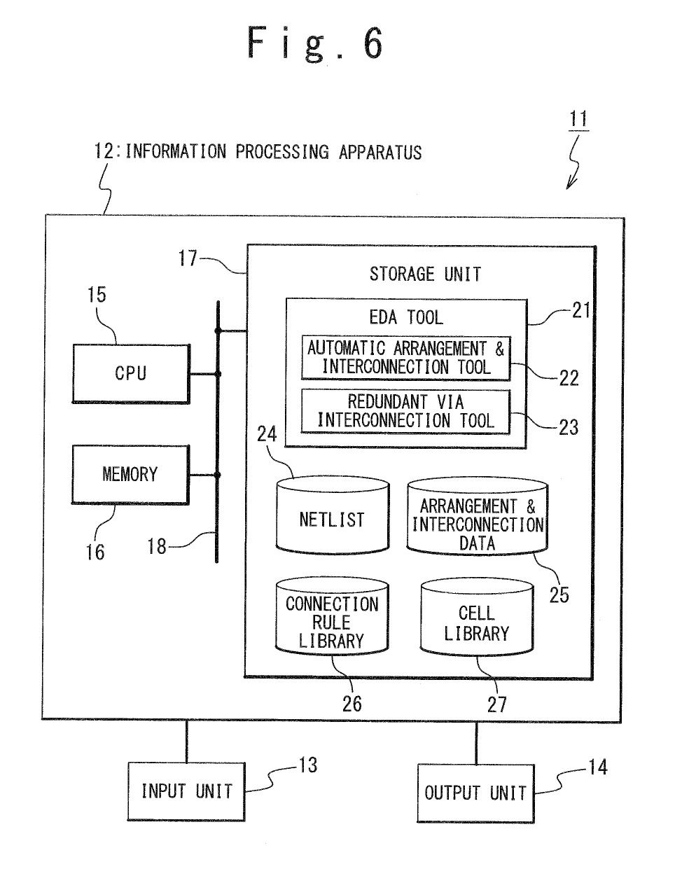

A design supporting apparatus for supporting design of the semiconductor integrated circuit 1 in the present embodiment will be described below. FIG. 6 is a block diagram showing a configuration of the semiconductor design supporting apparatus 11 for supporting design of the semiconductor integrated circuit 1 in the present embodiment. The semiconductor design supporting apparatus 11 includes an information processing apparatus 12, an input unit 13 and an output unit 14.

The information processing apparatus 12 is a computer which processes information at high speed according to a procedure instructed by a program which is installed from a recording medium (not shown). The information processing apparatus 12 has five functions: input, storage, calculation, control and output. In the present embodiment, the information processing apparatus 12 operates according to the procedures instructed by an automatic arrangement and interconnection tool 22 and a redundant via-contact interconnection tool 23, to be described later, of an Electronic Design Automation (EDA) tool 21. The input unit 13 is a man-machine interface for inputting data to the information processing apparatus 12. The input unit 13 is typically exemplified as a keyboard or a mouse. The output unit 14 is a man-machine interface for outputting processing results of the information processing apparatus 12. The output unit 14 is typically exemplified as a display device or a printer.

The information processing apparatus 12 has a CPU 15, a memory 16 and a storage unit 17, which are interconnected via a bus 18. The CPU 15 controls various devices equipped in the information processing apparatus 12 and processes data inputted/outputted by the input unit 13 and the output unit 14. The CPU 15 interprets and calculates the data received from the input unit 13 or the like and outputs calculation results by the output unit 14 or the like. The memory 16 is a storage medium capable of writing and reading data. The memory 16 is used as a main memory when the CPU 15 executes software. The memory 16 is typically exemplified as a DRAM or a SRAM. The storage unit 17 is a storage having a function of holding stored information without depending on ON/OFF of a power source. The storage unit 17 has an EDA tool 21. The storage unit 17 further has a netlist 24, arrangement and interconnection data 25, a connection rule library 26 and a cell library 27.

An operation for designing the semiconductor integrated circuit 1 in the present embodiment will be described below. The redundant via-contact interconnection tool 23 performs a predetermined process in response to the arrangement and interconnection result generated by the automatic arrangement and interconnection tool 22. Thus, the semiconductor integrated circuit 1 in the present embodiment is formed. The automatic arrangement and interconnection tool 22 performs a floor planning based on the netlist 24, the arrangement and interconnection data 25, the connection rule library 26 and the cell library 27, and then automatically arranges cells at optimum locations. After that, based on the netlist 24, the automatic arrangement and interconnection tool 22 automatically carries out interconnection between the cells, thereby generating the above-mentioned arrangement and interconnection result.

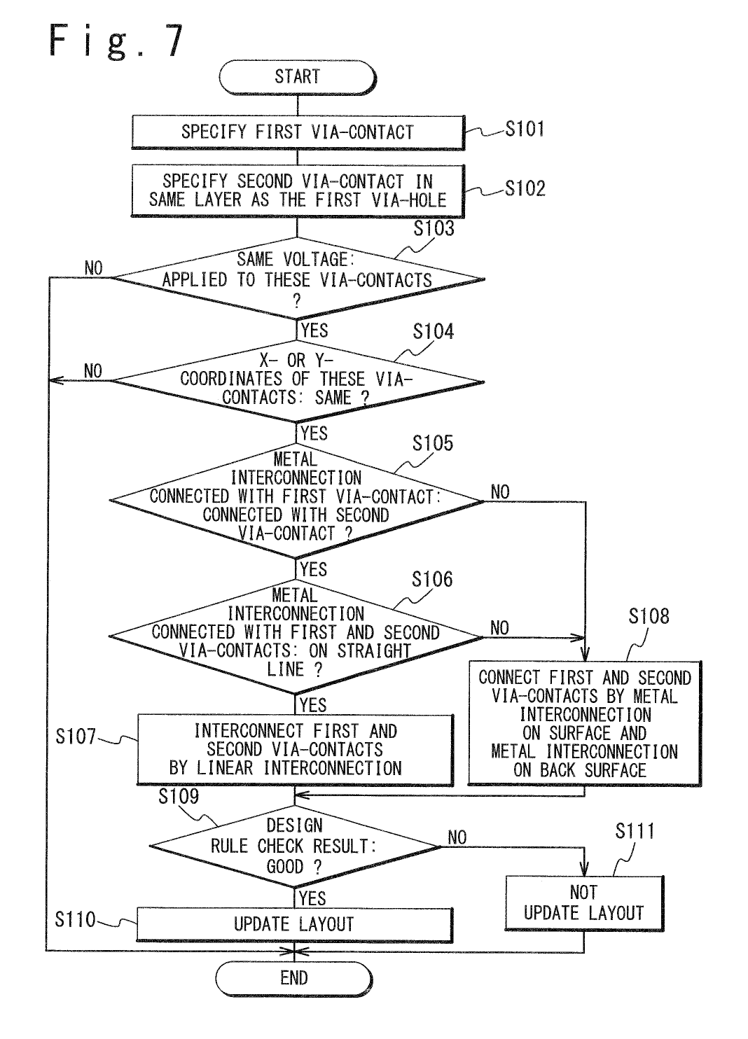

FIG. 7 is a flow chart showing an operation of the redundant via-contact interconnection tool 23. The redundant via-contact interconnection tool 23 performs the following operation on all via-contacts shown by the arrangement and interconnection result. Referring to FIG. 7, at Step S101, one of a plurality of via-contacts is identified and specified as a first via-contact. At Step S102, a via-contact formed in the same interlayer insulating film as the first via-contact 2 is identified and specified as a second via-contact 3.

At Step S103, it is determined whether or not a voltage applied to the first via-contact 2 is same as a voltage applied to the second via-contact 3. When the voltage applied to the first via-contact 2 is the same as the voltage applied to the second via-contact 3, a process flow advances to Step S104, and when the voltage applied to the first via-contact 2 is different from the voltage applied to the second via-contact 3, the process flow ends.

At Step S104, position coordinates of the first via-contact 2 and the second via-contact 3 are extracted. Based on the extracted position coordinates, it is determined whether or not an X coordinate of the first via-contact 2 and an X coordinate of the second via-contact 3 are coincident with each other or whether or not a Y coordinate of the first via-contact 2 and a Y coordinate of the second via-contact 3 are coincident with each other. When the X coordinates or the Y coordinates are coincident between the first via-contact 2 and the second via-contact 3, the process flow advances to Step S105 and when neither the X coordinates nor the Y coordinates are not coincident with each other between the first via-contact 2 and the second via-contact 3, the process flow ends.

At Step S105, a metal interconnection in contact with the first via-contact 2 is identified and specified and it is determined whether or not the metal interconnection is in contact with the second via-contact 3. When the metal interconnection is in contact with the second via-contact 3, the process flow advances to Step S106, and when the metal interconnection is not in contact with the second via-contact 3, the process flow advances to Step 108.

At Step S106, it is determined whether or not the metal interconnection connecting the first via-contact 2 to the second via-contact 3 is formed on a straight line along the X-axis or the Y-axis direction. When the first via-contact 2 and the second via-contact 3 are not placed on the straight line, the process flow advances to Step S108. When the first via-contact 2 and the second via-contact 3 are formed on the straight line along the X-axis or Y-axis, the process flow advances to Step 107.

At Step S107, a new metal interconnection linearly connecting the first via-contact 2 to the second via-contact 3 is formed in an interconnection layer where no metal interconnection connecting the first via-contact 2 to the second via-contact 3 is formed. For example, when the first via-contact 2 is previously connected to the second via-contact in a lower layer side, the first via-contact 2 is also connected to the second via-contact 3 by the metal interconnection in an upper layer side.

At Step S108, since the voltage applied to the first via-contact 2 is same as the voltage applied to the second via-contact 3 and the first via-contact 2 and the second via-contact 3 are not connected on a straight line by any metal interconnection, an upper end of the first via-contact 2 is connected to an upper end of the second via-contact 3 by a metal interconnection, and a lower end of the first via-contact 2 is connected to a lower end of the second via-contact 3 by a metal interconnection.

At Step S109, in a state that the upper ends of the first via-contact 2 and the second via-contact 3 are connected to each other and the lower ends of the first via-contact 2 and the second via-contact 3 are connected to each other, a design rule check is carried out. As a result, when DRCviolation (such as a spacing error and a short-circuit error) does not occur, the process flow advances to Step S110, and when DRCviolation occurs, the process flow advances to Step S111.

At Step S110, an interconnection layout in which the first via-contact 2 acts as the redundant via-contact for the second via-contact 3 and vice versa is established, and the interconnection layout is used as an interconnection layout of the semiconductor integrated circuit 1. At Step S111, since DRCviolation occurs, the process flow ends without changing the layout.

In the operation in the above-mentioned embodiment, when determination is made at the Step S109, the above-mentioned determination may be made on the metal interconnection arranged in the upper interconnection layer of the interlayer insulating film having the first via-contact 2 (or the second via-contact 3), and then, on the metal interconnection arranged in the lower interconnection layer.

Alternatively, after the determination at Step 109 is made on the metal interconnection arranged in the upper interconnection layer on the interlayer insulating film having the first via-contact 2 (or the second via-contact 3), the following process flow may be performed without determining on the metal interconnection arranged in the lower interconnection layer. In this case, when the result of determination at each step is NO, the operation in the present embodiment can be suitably performed by determining the metal interconnection arranged in the lower interconnection layer. It should be noted that determination on the lower layer of the interlayer insulating film may be made first.

### Second Embodiment

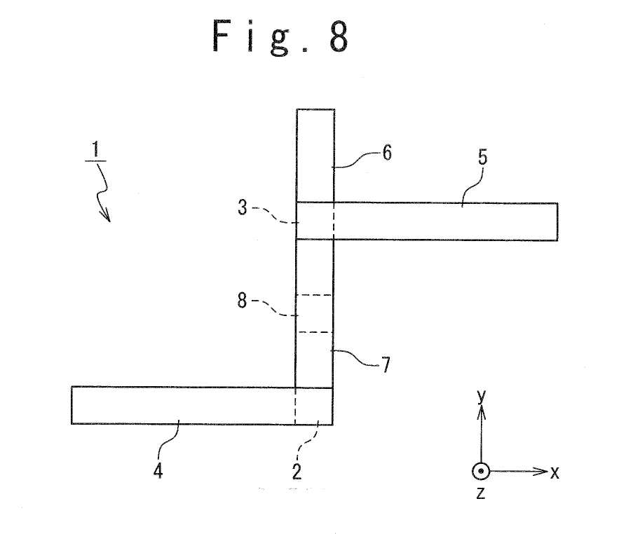

Referring to figures, a second embodiment of the present invention will he described below. FIG. 8 is a plan view showing a configuration of the semiconductor integrated circuit 1 in a second embodiment. The semiconductor integrated circuit 1 in the second embodiment is further obtained by adding a third via-contact 8 to the semiconductor integrated circuit 1 in the first embodiment. As shown in FIG. 8, the third via-contact 8 is arranged between the first via-contact 2 and the second via-contact 3.

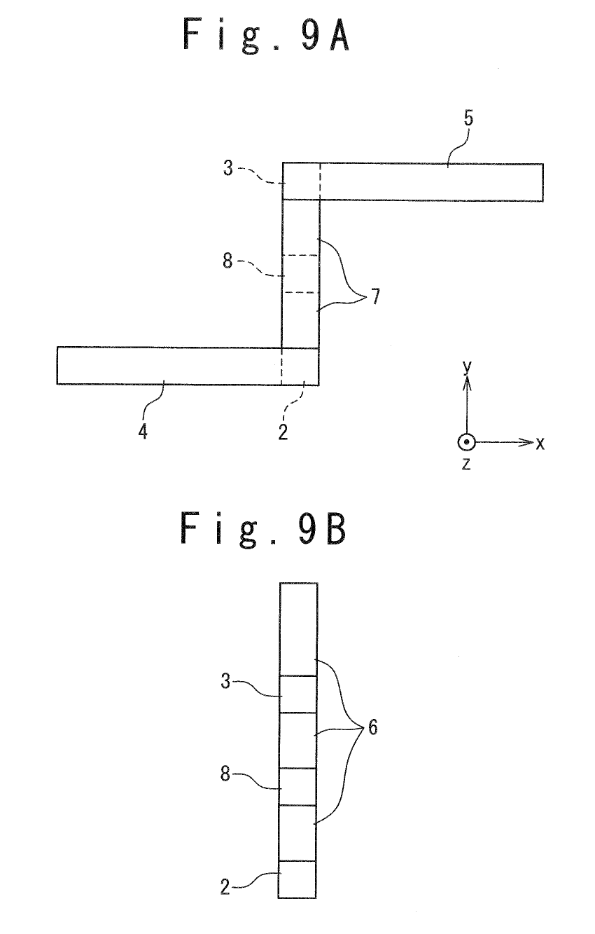

FIGS. 9A and 9B are plan views showing a configuration of the semiconductor integrated circuit 1 in the second embodiment for each interconnection layer. FIG. 9A shows an upper layer interconnection portion formed on the interlayer insulating film having the first via-contact 2 or the second via-contact 3. FIG. 9B shows a lower layer interconnection portion formed under the interlayer insulating film. As shown in FIG. 9A and 9B, the third via-contact 8 is connected to the redundant interconnection 7 and the lower layer interconnection 6 in the semiconductor integrated circuit 1 in the second embodiment.

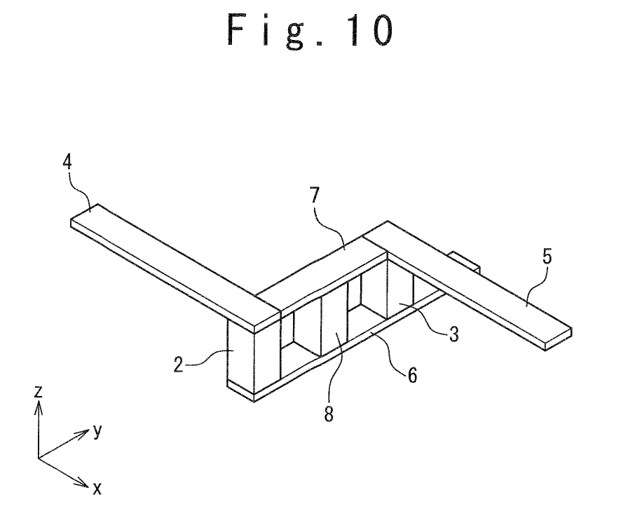

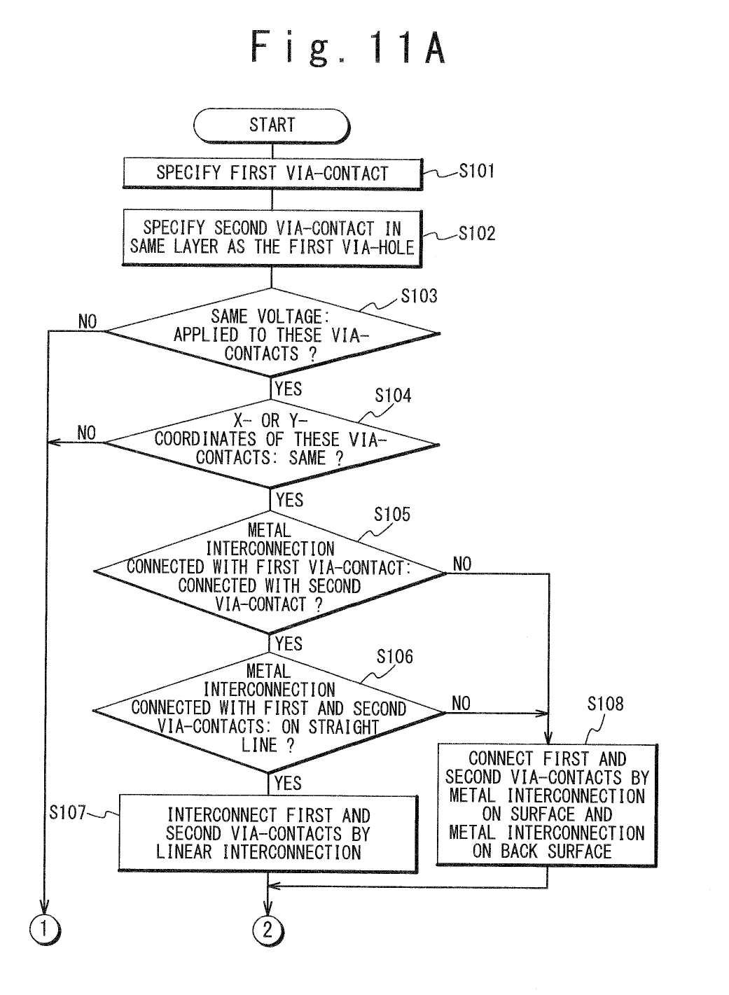

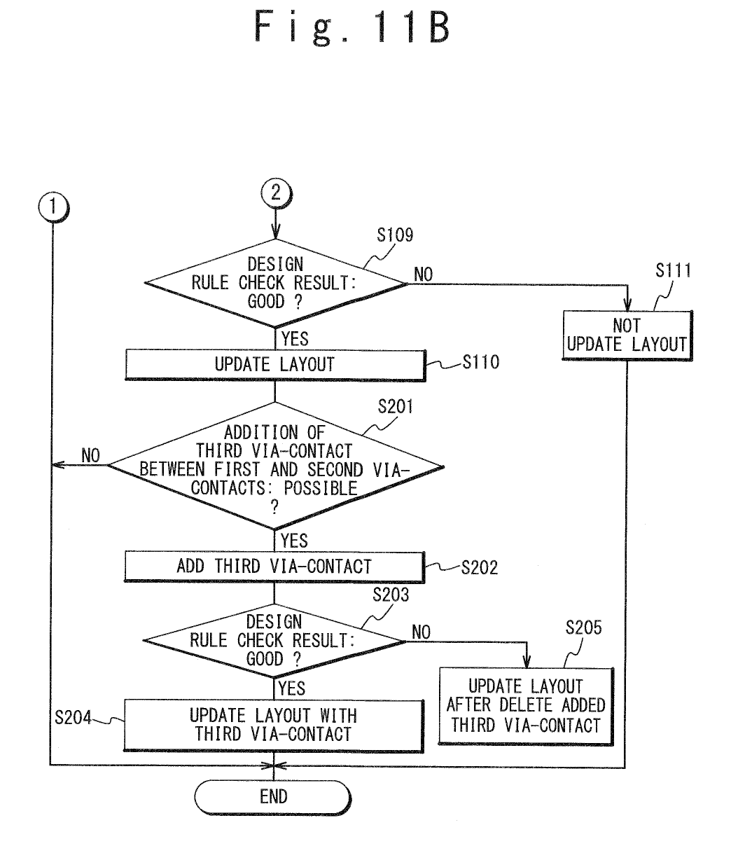

FIG. 10 is a perspective view showing a configuration of the semiconductor integrated circuit 1 in the second embodiment. Referring to FIG. 10, the third via-contact 8 is arranged between the first via-contact 2 and the second via-contact 3, and connects the lower layer interconnection on 6 to the redundant interconnection 7. Thereby, in the semiconductor integrated circuit in the second embodiment, even if the first via-contact 2 or the second via-contact 3 is not suitably formed, a suitable operation can be achieved since the third via-contact 8 acts as a redundant via-contact.

FIG. 11 is a flow chart showing an operation of the semiconductor integrated circuit 1 in the second embodiment. The operation at Steps S101 to Step S111 in the second embodiment is same as those in the first embodiment. Referring to FIG. 11, at Step S201, it is determined whether or not the third via-contact 8 can be added between the first via-contact 2 and the second via-contact 3. When the third via-contact 8 can be arranged, the process flow advances to Step S202, and when the third via-contact 8 cannot be arranged, the process flow ends.

At Step S202, the third via-contact 8 is arranged between the first via-contact 2 and the second via-contact 3. At Step S203, a design check rule to the semiconductor integrated circuit 1 having the third via-contact 8 is performed. When no DRCviolation (such as spacing error and short error) occurs, the process flow advances to Step S204. When the DRCviolation occurs, the process flow advances to Step S205 and a layout is updated to a layout having no third via-contact 8 (the layout updated at Step S110). At Step S204 an interconnection layout in which the first via-contact 2, the second via-contact 3 and the third via-contact 8 each act as the redundant via-contact for one another is established and the interconnection layout is used as an interconnection layout for the semiconductor integrated circuit 1.

In the above-mentioned second embodiment, to facilitate understanding of the present embodiment, a configuration and operation when one third via-contact 8 is arranged between the first via-contact 2 and the second via-contact 3 have been described. However, in the second embodiment, the number of via-contacts to be added is not limited. For example, if a plurality of new via-contacts can be arranged, it is preferred that the plurality of via-contacts are arranged to configure the semiconductor integrated circuit 1.

Although the present invention has been described above in connection with several embodiments thereof, it would be apparent to those skilled in the art that those embodiments are provided solely for illustrating the present invention, and should not be relied upon to construe the appended claims in a limiting sense.

What is claimed is:

1. A semiconductor integrated circuit comprising:
a first via-contact configured to connect a first interconnection pattern provided for a first interconnection layer and a second interconnection pattern provided for a second interconnection layer;
a second via-contact configured to connect a third interconnection pattern provided for said first interconnection layer and said second interconnection pattern; and
a redundant interconnection pattern formed in said first interconnection layer and configured to connect said first interconnection pattern and said third interconnection pattern to overlap above said second interconnection pattern.

2. The semiconductor integrated circuit according to claim 1, wherein said redundant interconnection pattern is provided between said first via-contact and said second via-contact to extend in a direction said second interconnection pattern.

3. The semiconductor integrated circuit according to claim 1, further comprising:
a third via-contact configured to connect said redundant interconnection pattern and said second interconnection pattern,
wherein said third via-contact is arranged between said first via-contact and said second via-contact.

4. The semiconductor integrated circuit according to claim 1, wherein said first interconnection layer is an n^{th} interconnection layer (n is an optional natural number), and
said second interconnection layer is an (n+1)^{th} or (n−1)^{th} interconnection layer.

5. A layout method of a semiconductor integrated circuit, comprising:
determining an interconnection layout of a semiconductor integrated circuit based on a netlist, a cell library and a connection rule;
specifying a first interconnection layer, a second interconnection layer, a first via-contact and a second via-contact, wherein an interlayer insulating film is provided between said first interconnection layer and said second interconnection layer, and said first and second via-contacts are formed in said interlayer insulating film, and applied with a same voltage;
checking whether or not a line between said first and second via-contacts extends along one of an X-axis and a Y-axis;
checking a first interconnection pattern in said first interconnection layer of whether or not said first interconnection pattern is provided to connect said first and second via-contacts at their first ends, when the line extends along one of the X-axis and the Y-axis;
checking whether or not said first interconnection pattern is a linear pattern;
providing a redundant interconnection pattern to connect said first and second via-contacts at their second ends opposite to the first ends, when said first interconnection pattern is a linear pattern; and
performing a design rule check on an interconnection layout with said redundant interconnection pattern added.

6. The layout method according to claim 5, further comprising:
connecting the first end of said first via-contact and the first end of said second via-contact straight by said redundant interconnection pattern on a straight line, when said first interconnection pattern connected with the first end of said first via-contact is not connected with the first end of said second via-contact; and
connecting the second end of said first via-contact and the second end of said second via-contact by said redundant interconnection pattern on a straight line.

7. The layout method according to claim 5, further comprising:
arranging a third via-contact between said first via-contact and said second via-contact.

8. A computer-readable recording medium in which a computer-readable program code is stored to realize a layout method of a semiconductor integrated circuit, wherein said layout method comprises:
determining an interconnection layout of a semiconductor integrated circuit based on a netlist, a cell library and a connection rule;
specifying a first interconnection layer, a second interconnection layer, a first via-contact and a second via-contact, wherein an interlayer insulating film is provided between said first interconnection layer and said second interconnection layer, and said first and second via-contacts are formed in said interlayer insulating film, and applied with a same voltage;
checking whether or not a line between said first and second via-contacts extends along one of an X-axis and a Y-axis;
checking a first interconnection pattern in said first interconnection layer of whether or not said first interconnection pattern is provided to connect said first and second via-contacts at their first ends, when the line extends along one of the X-axis and the Y-axis;
checking whether or not said first interconnection pattern is a linear pattern;
providing a redundant interconnection pattern to connect said first and second via-contacts at their second ends opposite to the first ends, when said first interconnection pattern is a linear pattern; and
performing g a design rule check on an interconnection layout with said redundant interconnection pattern added.

9. The computer-readable recording medium according to claim 8, wherein said layout method further comprises:
connecting the first end of said first via-contact and the first end of said second via-contact straight by said redundant interconnection pattern on a straight line, when said first interconnection pattern connected with the first end of said first via-contact is not connected with the first end of said second via-contact; and
connecting the second end of said first via-contact and the second end of said second via-contact by said redundant interconnection pattern on a straight line.

10. The computer-readable recording medium according to claim 8, wherein said layout method further comprises:
arranging a third via-contact between said first via-contact and said second via-contact.
